(19) United States
(12) Patent Application Publication
(10) Pub. No.: US 2005/0115924 A1
(43) Pub. Date: Jun. 2, 2005

(54) Integration function of RF signal to analyze steady state and non-steady state ( initializaion) of plasmas

(76) Inventors: Justin Sato, Portland, OR (US); Jeffrey Rask, Gresham, OR (US); Chris Bowker, Gresham, WA (US)

Correspondence Address: LSI LOGIC CORPORATION, 1621 BARBER LANE, MS: D-106, MILPITAS, CA, 95035, US

(21) Appl. No.: 10/725,139

(22) Filed: Dec. 1, 2003

(51) Int. Cl. G01R 31/00

(52) U.S. Cl. 216/59

(57) ABSTRACT

An integration function of an RF signal (i.e., a Fourier Transform of the voltage, current, phase and up to the fourth respective harmonic) is used to determine and predict etch rate and other etch chamber conditions. Different parts of the RF signal curve are integrated, thereby effectively separating the various zones of the signal, especially the strike and the steady state steps. After the parts are separated, each piece is analyzed separately and their contributions calculated and analyzed. By separating the etch into steps such as strike and the steady state, the effect of each process step on the total etch can be determined. The process can be used in plasma processing, equipment troubleshooting, and non-steady state plasma monitoring.

### BACKGROUND

The present invention generally relates to plasma processing, and more specifically relates to methods for analyzing the dynamics of plasma while in a non-steady state condition.

Fabricating a semiconductor device is a multiple-step process. At various stages of the fabrication, thin films of dielectrics, semiconductors and metals are formed on the wafer and then patterned and etched. Dry etching using plasma is an etching process which is widely-used in the industry.

In dry etching, the plasma is ignited using radio frequency (RF) power, the initiation of which takes between 3-5 seconds. During this 3-5 second initiation, referred to as the strike step, the plasma is in a non-steady state condition while the gases, pressure and RF are stabilizing. Currently in the industry, there are no robust methods for analyzing the dynamics of the plasma during this phase. As such, it is not possible to dial in the initiation steps or understand the variability which is introduced during the initializing step of processing, and the total etch rate cannot be accurately calculated so precise adjustments can be made in real time.

The second section of the dry etch process is called the steady state zone. During this period, the plasma has reached an equilibrium state and parameters associated with the plasma have stabilized and holding steady. The final step of the etch is called the extinction zone, the fraction of a second during which the plasma extinguishes. FIG. 4 illustrates the three zones of a typical dry etch plasma step, wherein zone A is the strike step, zone B is steady state, and zone C is extinction.

One prior art solution which is available is to use an average of the steady state to describe the initiation phase. More specifically, when an error occurs, an estimated time is used to finish processing. An average value of the steady state plasma etch rate is used to estimate the etch rate of the initiation period. However, this is not an accurate depiction of the plasma during the initiation, non-steady state phase. The variability associated with the non-steady state is not taken into account in calculating etch rate. Instead, it is approximated into the entire cycle using an average approximation based on steady state characteristics. As the film stacks continue to decrease due to smaller geometries, the error from the strike step becomes a larger factor for control and stability.

Another prior art solution is to perform an etching process using one set of parameters, and then measure the etch rate, change the parameters to adjust for any variations in etch rate, and re-etch. Measuring etch rates is time-consuming and results are not obtained in real time. During the interrupted processing of material, a best guess is used to compensate and re-work the material. For very short re-work times or very thin films, this can lead to the scrapping of product due to the lack of control. Additionally, variations in the chamber hardware may lead to shifts in chamber conditions. The only way to truly examine these parts is to open the chamber which may require 8-20 hours of recovery time. There are very few tools which can be used to monitor the parts in the chamber in real time without opening the chamber.

One cutting edge prior art solution is to read and analyze plasma impedance signals once the RF signal has gone steady state. However, this method does not deal with the initiation (i.e., non-steady state) of the plasma. The method also only measures a portion of the etch and may not represent the total etch. The method does not allow for the monitoring of strike health, transition step changes, or process shifts.

### OBJECTS AND SUMMARY

An object of an embodiment of the present invention is to analyze the non-steady state of plasma in an etching process.

Another object of an embodiment of the present invention is to provide a real time analysis of plasma conditions through steady state as well as non-steady state.

Still another object of an embodiment of the present invention is to better understand the variations that take place during initiation of plasma in an etching process.

Still yet another object of an embodiment of the present invention is to predict wear of chamber hardware components and accurately report on the respective plasma condition changes (e.g., pressure, density and power).

Still yet another object of an embodiment of the present invention is to provide a technique which can be used in plasma processing for equipment matching, equipment troubleshooting, and non-steady state plasma monitoring.

Briefly, and in accordance with at least one of the foregoing objects, an embodiment of the present invention provides a method wherein an integration function of an RF signal is used to determine and predict etch rate and other etch chamber conditions (e.g., pressure, flow, gap spacing, hardware variations etc.). Different parts of the RF signal curve are integrated, thereby effectively separating the various phases of the signal, especially the steady state and the non-steady state. After the parts are separated, each piece is analyzed separately and their contributions calculated and analyzed. By separating the etch into steps such as strike and the steady state zones, the effect of each process step on the total etch can be determined.

### BRIEF DESCRIPTION OF THE DRAWINGS

The organization and manner of the structure and operation of the invention, together with further objects and advantages thereof, may best be understood by reference to the following description, taken in connection with the accompanying drawing, wherein:

FIG. 1 is a flow chart which illustrates a method which is in accordance with an embodiment of the present invention;

FIG. 2 is a block diagram which illustrates an RF signal monitor which can be used in connection with the method shown in FIG. 1;

FIG. 3 is a plot which demonstrates the relationship between etch rate and f(Vo) for different system conditions;

FIG. 4 is a representative plot of the raw data collected during a plasma process;

FIG. 5 is a graph which plots V4 (i.e., the vertical axis) versus VO (i.e., the horizontal axis); and

FIG. 6 is a graph which plots etch rate (i.e., the vertical axis) versus VO (i.e., the horizontal axis).

### DESCRIPTION

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

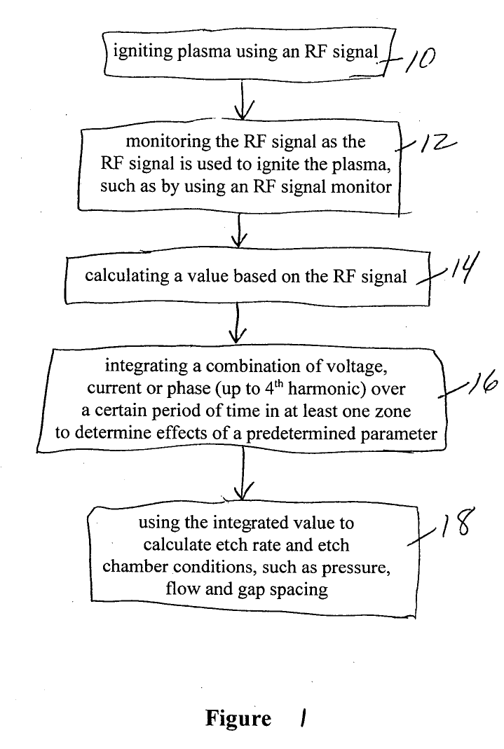

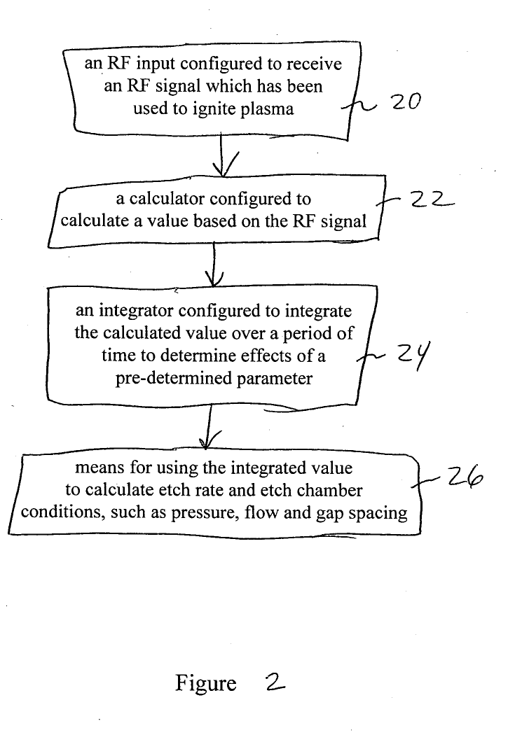

FIG. 1 illustrates a method of analyzing plasma, and FIG. 2 illustrates an RF signal monitor which can be used in connection with the method illustrated in FIG. 1. The method provides that the non-steady state of plasma can be analyzed in an etching process. Specifically, plasma conditions can be analyzed in real time, through steady state as well as non-steady state. As a result, the variations which take place during initiation of plasma in an etching process can be better understood. Additionally, the wear of chamber hardware components can be more accurately predicted, and plasma condition changes (e.g., pressure, density and power) can be reported with more accuracy. The embodiments can be used in plasma processing, non-steady state plasma monitoring and equipment troubleshooting.

As shown in FIG. 1, the method provides: igniting the plasma using an RF signal (box 10 in FIG. 1), monitoring the RF signal as the RF signal is used to ignite the plasma (box 12 in FIG. 1), calculating a value based on the RF signal (box 14 in FIG. 1), and integrating the calculated value over a period of time to determine effects of a pre-determined parameter (box 16 in FIG. 1). Preferably, an RF signal monitor is used to monitor the RF signal and calculate the value, then, a separate device is used to integrate the calculated value. Preferably, the step of integrating the calculated value comprises applying a Reimann Sum. Preferably, the developed algorithm uses the integrated value to calculate etch rate and etch chamber conditions, such as pressure, flow and gap spacing (box 18 in FIG. 1). Preferably, a plurality of parts of the RF signal are integrated.

Therefore, the method provides that an integration function of an RF signal over a certain period of time is used to determine and predict etch rate and other etch chamber conditions (e.g., pressure, flow, gap spacing, etc.). Different parts of the RF signal curve are integrated, thereby effectively separating the various zones of the signal, especially the steady state and the non-steady state. After the parts are separated, each piece is analyzed separately and their contributions calculated and analyzed. By separating the etch into steps such as strike and the bulk etch, the effect of each process step on the total etch can be determined.

FIG. 2 illustrates an RF signal monitor that can be utilized in association with the method illustrated in FIG. 1. The RF signal monitor is configured to analyze a plasma, and includes an RF input configured to receive an RF signal which has been used to ignite plasma (box 20 in FIG. 2), a calculator configured to calculate a value based on the RF signal (box 22 in FIG. 2), and a separate device to integrate the calculated value over a period of time to determine effects of a pre-determined parameter (box 24 in FIG. 2). Preferably, the integrator is configured to apply an integration algorithm over various steps and separate zones of the plasma. Preferably, the RF signal monitor is configured to use the integrated value to calculate etch rate and etch chamber conditions, such as pressure, flow and gap spacing (box 26 in FIG. 2). Preferably, the integrator is configured to integrate a plurality of parts of the RF signal. By integrating different parts of the RF signal curve, the various steps and zones of the signal are effectively separated, especially the steady state and the non-steady state. After the parts are separated, each piece is analyzed separately and their contributions calculated and analyzed. By separating the etch into steps such as strike and the steady state zones, the effect of each zone on the total etch can be determined. The invention can be embodied in hardware and/or software.

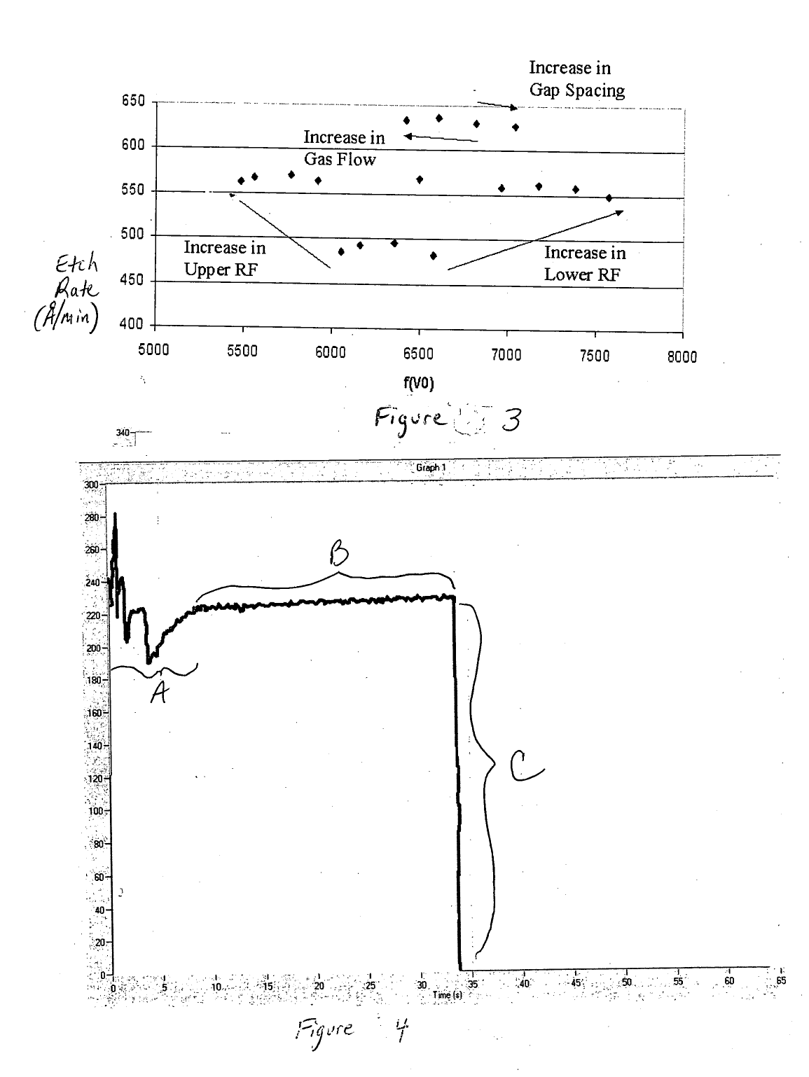

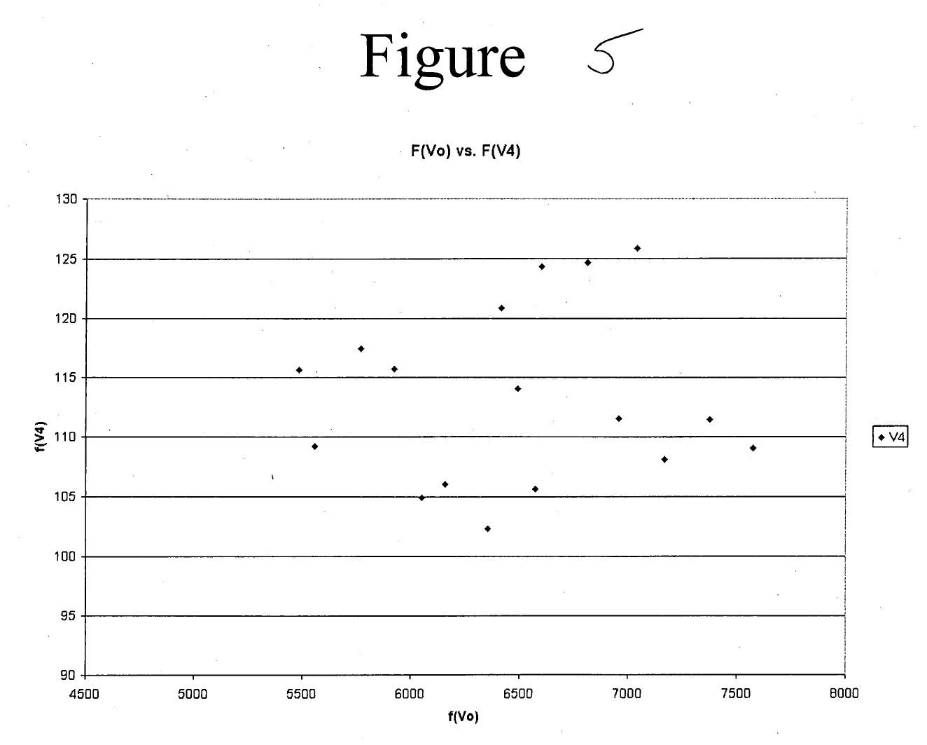

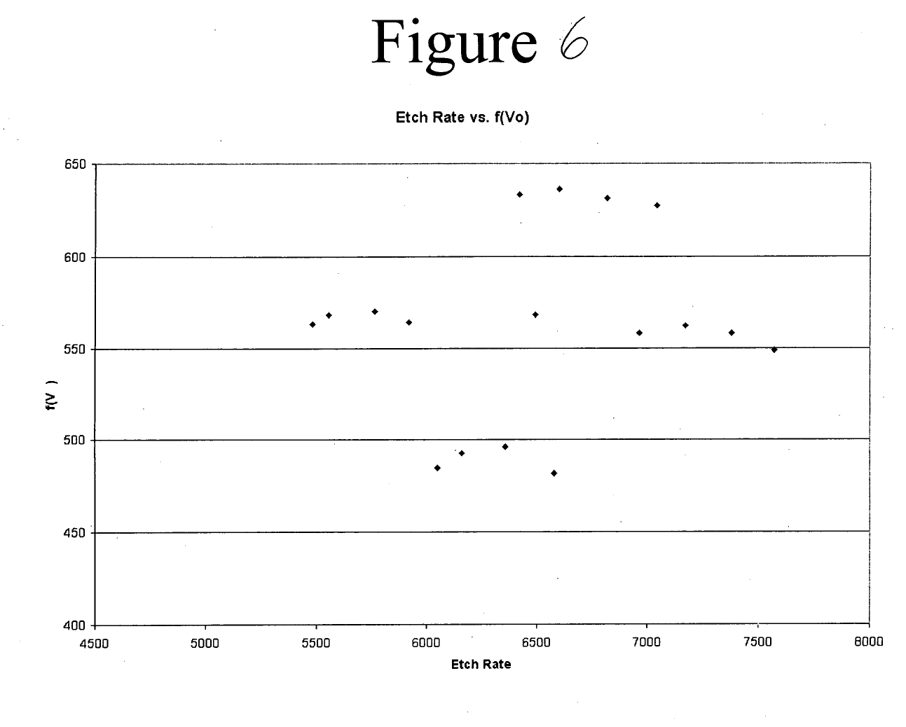

FIGS. 3-6 are four graphs which are associated with the present invention. Specifically, FIG. 3 is a graph which plots the etch rate (i.e., the vertical axis) versus an integrated value function (f(VO)) (i.e., the horizontal axis). FIG. 4 is a graph which plots raw voltage as collected by an RF signal monitor (i.e., the vertical axis) versus time (i.e., the horizontal axis). The plot is separated to represent the 3 zones of a typical plasma, strike step (zone A), steady state (zone B) and extinction (zone C). FIG. 5 is a graph that plots V4 (i.e., the vertical axis) versus V0 (i.e., the horizontal axis), and represents a basic modeling function. Finally, FIG. 6 is a graph which plots etch rate (i.e., the vertical axis) versus V0 (i.e., the horizontal axis) for comparison to FIG. 5.

While an embodiment of the present invention is shown and described, it is envisioned that those skilled in the art may devise various modifications of the present invention without departing from the spirit and scope of the appended claims.

1. A method of analyzing plasma, said method comprising: igniting the plasma using an RF signal; monitoring the RF signal as the RF signal is used to ignite the plasma; calculating a value based on the RF signal; integrating the calculated value over a period of time to determine effects of a pre-determined parameter.

2. The method as recited in claim 1, further comprising using an RF signal monitor to monitor the RF signal, calculate the value, and integrate the calculated value.

3. The method as recited in claim 1, further comprising using the integrated value to calculate etch rate.

4. The method as recited in claim 1, further comprising using the integrated value to calculate at least one etch chamber condition.

5. The method as recited in claim 1, further comprising using the integrated value to calculate at least one of pressure, flow and gap spacing associated with an etch chamber.

6. The method as recited in claim 1, further comprising integrating a plurality of parts of the RF signal.
